(19) United States
(12) Patent Application Publication
(10) Pub. No.: US 2025/0326218 A1
(43) Pub. Date: Oct. 23, 2025

(54) METHOD OF MANUFACTURING DISPLAY APPARATUS

(71) Applicant: Samsung Display Co., Ltd., Yongin-si (KR)

(72) Inventors: Donghun KANG, Yongin-si (KR); Seongsik CHOI, Yongin-si (KR); Seungho KIM, Yongin-si (KR); Yongwoo KIM, Yongin-si (KR); Hoyun BYUN, Yongin-si (KR); Donghyeon LEE, Yongin-si (KR); Jeongin LEE, Yongin-si (KR); Jeongseop CHOI, Yongin-si (KR)

(21) Appl. No.: 19/175,268

(22) Filed: Apr. 10, 2025

(30) Foreign Application Priority Data
Apr. 22, 2024 (KR) 10-2024-0053542

(51) Int. Cl. B32B 37/12; B32B 38/00; C09J 5/00; C09J 133/06; C09J 133/14; H10K 59/80; H10K 77/10; H10K 102/00

(52) U.S. Cl. CPC B32B 37/1292; C09J 5/00; C09J 133/066; C09J 133/14; H10K 59/871; H10K 59/8791; H10K 77/111; B32B 2037/1253; B32B 2038/0076; B32B 2457/20; H10K 2102/311

(57) ABSTRACT

A method of manufacturing a display apparatus includes preparing a display panel with a functional layer attached to a surface of the display panel. The display panel includes a first non-folded area, a second non-folded area, and a foldable area between the first non-folded area and the second non-folded area, and forming a preliminary lower adhesive layer on the functional layer. The forming the preliminary lower adhesive layer includes coating a first adhesive composition on a portion of the functional layer that overlaps the first non-folded area and the second non-folded area and coating a second adhesive composition on another portion of the functional layer that overlaps the foldable area. During the forming the preliminary lower adhesive layer, the coating the first adhesive composition and the coating the second adhesive composition are simultaneously performed.

This application claims priority to Korean Patent Application Nos. 10-2024-0053542, filed on Apr. 22, 2024, and all the benefits accruing therefrom under 35 U.S.C. § 119, the content of which in its entirety is herein incorporated by reference.

### BACKGROUND

### 1. Field

Embodiments relate to a method of manufacturing a display apparatus, and more particularly, to a method of manufacturing a display apparatus, which may reduce a possibility of defects occurring during a manufacturing process.

### 2. Description of the Related Art

Display apparatuses may be utilized as various electronic apparatuses. For example, display apparatuses may be mobile electronic apparatuses such as smartphones. Such electronic apparatuses may be foldable electronic apparatuses in which a portion of a display surface thereof is folded to increase the area of a display area thereof while reducing the overall size. That is, the display apparatus may include a non-folded area and a foldable area.

The display apparatus may include a plurality of elements, and an adhesive layer may be disposed between the elements of the display apparatus to attach one element to another element of the display apparatus. The desired characteristics of the adhesive layer may be different depending on the position thereof in the display apparatus. Specifically, a portion of the adhesive layer located in the non-folded area of the display apparatus is desired to improve impact resistance of the display apparatus, and another portion of the adhesive layer located in the foldable area of the display apparatus is desired to improve folding characteristics. To satisfy these characteristics, different types of adhesive compositions are used to form the adhesive layer.

### SUMMARY

In display apparatuses according to the related art, an adhesive layer formed using different types of adhesive compositions is not flat.

Embodiments include a method of manufacturing a display apparatus, which may reduce a possibility of defects occurring during a manufacturing process. However, such a technical problem is an example, and the disclosure is not limited thereto.

Additional features will be set forth in part in the description which follows and, in part, will be apparent from the description, or may be learned by practice of the presented embodiments of the disclosure.

In an embodiment of the disclosure, a method of manufacturing a display apparatus includes preparing a display panel with a functional layer attached to one surface of the display panel, where the display panel includes a first non-folded area, a second non-folded area, and a foldable area between the first non-folded area and the second non-folded area, forming a preliminary lower adhesive layer on the functional layer, where the preliminary lower adhesive layer includes a preliminary first lower adhesive layer and a preliminary second lower adhesive layer, and forming a lower adhesive layer by irradiating an ultraviolet ray to the preliminary lower adhesive layer, where the lower adhesive layer includes a first lower adhesive layer cured from the preliminary first lower adhesive layer and a second lower adhesive layer cured from the preliminary second lower adhesive layer, where the forming of the preliminary lower adhesive layer includes forming the preliminary first lower adhesive layer overlapping the first non-folded area and the second non-folded area by coating a first adhesive composition on a portion of the functional layer that overlaps the first non-folded area and the second non-folded area, and forming the preliminary second lower adhesive layer overlapping the foldable area by coating a second adhesive composition on another portion of the functional layer that overlaps the foldable area, where each of the first adhesive composition and the second adhesive composition includes a first crosslinkable monomer including a hydroxyl group, a second crosslinkable monomer non-including a hydroxyl group, a third crosslinkable monomer including a heterocyclic group at a terminal thereof, a fourth crosslinkable monomer including an ethylene glycol group, and an oligomer, where a content of the second crosslinkable monomer contained in the first adhesive composition is less than a content of the second crosslinkable monomer contained in the second adhesive composition, and where, during the forming of the preliminary lower adhesive layer, the coating of the first adhesive composition and the coating of the second adhesive composition are simultaneously performed.

In an embodiment, a difference between the content of the second crosslinkable monomer contained in the first adhesive composition based on a total weight of the first crosslinkable monomer, the second crosslinkable monomer, the third crosslinkable monomer, the fourth crosslinkable monomer, and the oligomer included in the first adhesive composition, and the content of the second crosslinkable monomer contained in the second adhesive composition based on a total weight of the first crosslinkable monomer, the second crosslinkable monomer, the third crosslinkable monomer, the fourth crosslinkable monomer, and the oligomer included in the second adhesive composition, may be about 5 wt % to about 45 wt %.

In an embodiment, a difference between a dynamic surface tension of the first adhesive composition and a dynamic surface tension of the second adhesive composition may be about 0.1 millinewton per meter to about 1 millinewton per meter.

In an embodiment, a difference between a predetermined gravity of the first adhesive composition and a predetermined gravity of the second adhesive composition may be about 0.1 or less.

In an embodiment, a modulus of the first lower adhesive layer may be about 1.5 megapascals (MPa) or more, and a modulus of the second lower adhesive layer may be about 0.03 MPa to about 1.5 MPa.

In an embodiment, a difference between a refractive index of the first lower adhesive layer and a refractive index of the second lower adhesive layer may be about 0.1 or less.

In an embodiment, the first crosslinkable monomer may include at least one of 4-hydroxybutyl (meth)acrylate, 2-hydroxypropyl (meth)acrylate, 2-hydroxyethyl (meth)acrylate, and dihydroxyhexyl (meth)acrylate.

The second crosslinkable monomer may include at least one of 2-ethylhexyl (meth)acrylate, ethyl (meth)acrylate, methyl (meth)acrylate, n-propyl (meth)acrylate, isopropyl (meth)acrylate, pentyl (meth)acrylate, n-octyl (meth)acrylate, isooctyl (meth)acrylate, isononyl (meth)acrylate, n-butyl (meth)acrylate, isobutyl (meth)acrylate, n-hexyl (meth)acrylate, n-nonyl (meth)acrylate, isoamyl (meth)acrylate, n-decyl (meth)acrylate, isodecyl (meth)acrylate, dodecyl (meth)acrylate, isobornyl (meth)acrylate, cyclohexyl (meth)acrylate, phenyl (meth)acrylate, benzyl (meth)acrylate, isostearyl (meth)acrylate, and 2-methylbutyl (meth)acrylate.

In an embodiment, the third crosslinkable monomer may include at least one of tetrahydrofurfuryl (meth)acrylate, (tetrahydro-2H-pyran-2-yl)methyl (meth)acrylate, (oxetan-2-yl)methyl (meth)acrylate, (oxepan-2-yl)methyl (meth)acrylate, (2-oxa-bicyclo[2.2.2]octan-6-yl)methyl (meth)acrylate, and (7-oxa-bicyclo[2.2.1]heptan-2-yl)methyl (meth)acrylate.

In an embodiment, the fourth crosslinkable monomer may include at least one of di(ethylene glycol) 2-ethylhexyl ether (meth)acrylate and ethylene glycol (meth)acrylate.

In an embodiment, the method may further include attaching a cover window to the functional layer using the lower adhesive layer.

In an embodiment, the method may further include forming a preliminary upper adhesive layer on the cover window, where the preliminary upper adhesive layer includes a preliminary first upper adhesive layer and a preliminary second upper adhesive layer, forming an upper adhesive layer by irradiating an ultraviolet ray to the preliminary upper adhesive layer, where the upper adhesive layer includes a first upper adhesive layer cured from the preliminary first upper adhesive layer and a second upper adhesive layer cured from the preliminary second upper adhesive layer, and attaching a protective film to the cover window using the upper adhesive layer, where the forming of the preliminary upper adhesive layer includes forming the preliminary first upper adhesive layer overlapping the first non-folded area and the second non-folded area by coating the first adhesive composition on a portion of the cover window that overlaps the first non-folded area and the second non-folded area, and forming the preliminary second upper adhesive layer overlapping the foldable area by coating the second adhesive composition on another portion of the cover window that overlaps the foldable area.

In an embodiment of the disclosure, a method of manufacturing a display apparatus includes forming a preliminary lower adhesive layer on a cover window, where the preliminary lower adhesive layer includes a preliminary first lower adhesive layer and a preliminary second lower adhesive layer, and forming a lower adhesive layer by irradiating an ultraviolet ray to the preliminary lower adhesive layer, where the lower adhesive layer includes a first lower adhesive layer cured from the preliminary first lower adhesive layer and a second lower adhesive layer cured from the preliminary second lower adhesive layer, where the forming of the preliminary lower adhesive layer includes forming the preliminary first lower adhesive layer by coating a first adhesive composition on a portion of the cover window, and forming the preliminary second lower adhesive layer by coating a second adhesive composition on another portion of the cover window, where each of the first adhesive composition and the second adhesive composition includes a first crosslinkable monomer including a hydroxyl group, a second crosslinkable monomer non-including a hydroxyl group, a third crosslinkable monomer including a heterocyclic group at a terminal thereof, a fourth crosslinkable monomer including an ethylene glycol group, and an oligomer, where a content of the second crosslinkable monomer contained in the second adhesive composition is less than a content of the second crosslinkable monomer contained in the first adhesive composition, and where, during the forming of the preliminary lower adhesive layer, the coating of the first adhesive composition and the coating of the second adhesive composition are simultaneously performed.

In an embodiment, a difference between the content of the second crosslinkable monomer contained in the first adhesive composition based on a total weight of the first crosslinkable monomer, the second crosslinkable monomer, the third crosslinkable monomer, the fourth crosslinkable monomer, and the oligomer included in the first adhesive composition, and the content of the second crosslinkable monomer contained in the second adhesive composition based on a total weight of the first crosslinkable monomer, the second crosslinkable monomer, the third crosslinkable monomer, the fourth crosslinkable monomer, and the oligomer included in the second adhesive composition, may be about 5 wt % to about 45 wt %.

In an embodiment, a difference between a dynamic surface tension of the first adhesive composition and a dynamic surface tension of the second adhesive composition may be about 0.1 millinewton per meter (mN/m) to about 1 mN/m.

In an embodiment, a difference between a predetermined gravity of the first adhesive composition and a predetermined gravity of the second adhesive composition may be about 0.1 or less.

In an embodiment, a modulus of the first lower adhesive layer may be about 1.5 MPa or more, and a modulus of the second lower adhesive layer may be about 0.03 MPa to about 1.5 MPa.

In an embodiment, a difference between a refractive index of the first lower adhesive layer and a refractive index of the second lower adhesive layer may be about 0.1 or less.

In an embodiment, the first crosslinkable monomer may include at least one of 4-hydroxybutyl (meth)acrylate, 2-hydroxypropyl (meth)acrylate, 2-hydroxyethyl (meth)acrylate, and dihydroxyhexyl (meth)acrylate.

In an embodiment, the second crosslinkable monomer may include at least one of 2-ethylhexyl (meth)acrylate, ethyl (meth)acrylate, methyl (meth)acrylate, n-propyl (meth)acrylate, isopropyl (meth)acrylate, pentyl (meth)acrylate, n-octyl (meth)acrylate, isooctyl (meth)acrylate, isononyl (meth)acrylate, n-butyl (meth)acrylate, isobutyl (meth)acrylate, n-hexyl (meth)acrylate, n-nonyl (meth)acrylate, isoamyl (meth)acrylate, n-decyl (meth)acrylate, isodecyl (meth)acrylate, dodecyl (meth)acrylate, isobornyl (meth)acrylate, cyclohexyl (meth)acrylate, phenyl (meth)acrylate, benzyl (meth)acrylate, isostearyl (meth)acrylate, and 2-methylbutyl (meth)acrylate.

In an embodiment, the third crosslinkable monomer may include at least one of tetrahydrofurfuryl (meth)acrylate, (tetrahydro-2H-pyran-2-yl)methyl (meth)acrylate, (oxetan-2-yl)methyl (meth)acrylate, (oxepan-2-yl)methyl (meth)acrylate, (2-oxa-bicyclo[2.2.2]octan-6-yl)methyl (meth)acrylate, and (7-oxa-bicyclo[2.2.1]heptan-2-yl)methyl (meth)acrylate.

In an embodiment, the fourth crosslinkable monomer may include at least one of di(ethylene glycol) 2-ethylhexyl ether (meth)acrylate and ethylene glycol (meth)acrylate.

In an embodiment, the method may further include attaching a display panel to the cover window using the lower adhesive layer, where the display panel includes a first non-folded area, a second non-folded area, and a foldable area between the first non-folded area and the second non-folded area, where the attaching of the display panel may include attaching the display panel to the cover window such that the first non-folded area and the second non-folded area overlap the first lower adhesive layer, and the foldable area overlaps the second lower adhesive layer.

These and/or other features will become apparent and more readily appreciated from the following description of the embodiments, the accompanying drawings, and claims.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display apparatus manufactured by a method of manufacturing a display apparatus;

FIG. 2 is a schematic cross-sectional view of an embodiment of a display apparatus manufactured by a method of manufacturing a display apparatus;

FIG. 3 is a schematic cross-sectional view of the display apparatus of FIG. 1, taken along line I-I′ of FIG. 1;

FIG. 4 is a schematic enlarged cross-sectional view of a region A of the display apparatus of FIG. 3;

FIG. 5 is a schematic cross-sectional view of a portion of a display panel included in the display apparatus of FIG. 3;

FIGS. 6 to 12 are schematic cross-sectional views for explaining an embodiment of a method of manufacturing a display apparatus;

FIG. 13 is a graph showing a thickness profile of an adhesive layer included in a display apparatus manufactured by a method of manufacturing a display apparatus, according to a comparative example;

FIG. 14 is a graph showing a thickness profile of an embodiment of an adhesive layer included in a display apparatus manufactured by a method of manufacturing a display apparatus; and

FIGS. 15 to 17 are schematic cross-sectional views for explaining an embodiment of a method of manufacturing a display apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

In the specification, “A and/or B” means A or B, or A and B. In the specification, “at least one of A and B” means A or B, or A and B.

In the specification, when various elements such as a layer, a region, a plate, and the like are disposed “on” another element, not only the elements may be disposed “directly on” the other element, but another element may be disposed therebetween.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the case where an illustrative embodiment may be implemented differently, a specific process order may be performed in the order different from the described order. As an example, two processes successively described may be simultaneously performed substantially and performed in the opposite order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments will be described with reference to the accompanying drawings, where like reference numerals refer to like elements throughout and a repeated description thereof is omitted. Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

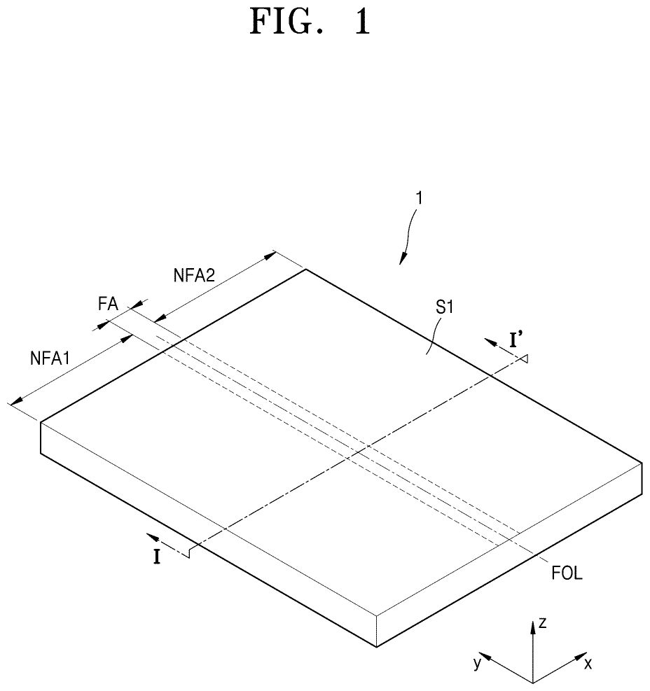

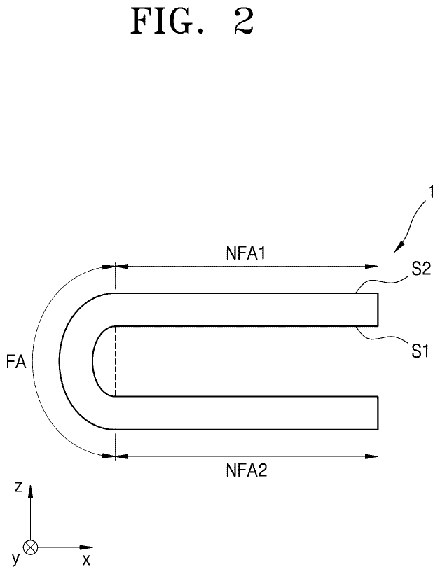

FIG. 1 is a schematic perspective view of an embodiment of a display apparatus 1 manufactured by a method of manufacturing a display apparatus in an embodiment, and FIG. 2 is a schematic cross-sectional view of the display apparatus 1 manufactured by a method of manufacturing a display apparatus. Specifically, FIG. 1 is a perspective view of the display apparatus 1 in an unfolded state, and FIG. 2 is a cross-sectional view of the display apparatus 1 in a folded state.

The display apparatus 1 may have a polygonal shape including quadrangles. In an embodiment, the display apparatus 1 may have a quadrangular shape, e.g., rectangular shape in which a horizontal length thereof is greater than a vertical length, a quadrangular shape, e.g., rectangular shape in which a horizontal length thereof is less than a vertical length, or a square shape. In an alternative embodiment, the display apparatus 1 may have various shapes such as an elliptical shape or a circular shape. Although it is shown in FIG. 1 that the display apparatus 1 has a quadrangular shape, e.g., rectangular shape in which a horizontal length is less than a vertical length, the disclosure is not limited thereto.

The display apparatus 1 may include a first surface S1 and a second surface S2 opposite the first surface S1. In an embodiment, the first surface S1 may be the upper surface (in a +z direction) of the display apparatus 1, and the second surface S2 may be the lower surface (in a −z direction) of the display apparatus 1. The display apparatus 1 may display images on the first surface S1. That is, the first surface S1 may include a display surface. In an embodiment, the display apparatus 1 may display images on also the second surface S2.

The display apparatus 1 may be folded. That is, at least a portion of the display apparatus 1 may be flexible, and when the flexible portion is bent, the display apparatus 1 may be folded. Accordingly, the display apparatus 1 may include a folded area and a non-folded area, that is, not folded area, provided to at least one side of the folded area. In the specification, “non-folded” means not folded, which includes not only a case of being inflexible and hard to be folded, but also a case of having flexibility but not being folded. The display apparatus 1 may display images in not only the non-folded area but also the folded area.

As shown in FIG. 1, the display apparatus 1 may include a first non-folded area NFA1, a second non-folded area NFA2, and a foldable area FA. The first non-folded area NFA1 and the second non-folded area NFA2 may be non-folded areas, and the foldable area FA may be a flexible region that may be folded.

The foldable area FA may extend in a direction crossing a virtual straight line connecting the first non-folded area NFA1 and the second non-folded area NFA2 to each other. Specifically, in the case where the display apparatus 1 is in an unfolded state, the first non-folded area NFA1 and the second non-folded area NFA2 may be spaced apart from each other in a first direction (e.g., an x-axis direction). The foldable area FA may be disposed between the first non-folded area NFA1 and the second non-folded area NFA2. Specifically, the first non-folded area NFA1 may be adjacent to one side of the foldable area FA, and the second non-folded area NFA2 may be adjacent to another side of the foldable area FA. In the case where the display apparatus 1 is in the unfolded state, the foldable area FA may extend in a second direction (e.g., a y-axis direction) crossing the first direction (e.g., the x-axis direction).

A folding line FOL may be provided in the foldable area FA in the second direction (e.g., the y-axis direction), which is the extension direction of the foldable area FA. Accordingly, the display apparatus 1 may be folded in the foldable area FA. The foldable area FA and the folding line FOL of the foldable area FA may overlap a region in which images of the display apparatus 1 are displayed. In the case where the display apparatus 1 is folded, a portion in which images are displayed may be folded.

For convenience of description, although it is shown in FIG. 1 that the first non-folded area NFA1 and the second non-folded area NFA2 have the same or similar area and the display apparatus 1 includes one foldable area FA, the disclosure is not limited thereto. In an embodiment, the first non-folded area NFA1 and the second non-folded area NFA2 may have different areas. In addition, the display apparatus 1 may include a plurality of foldable areas FA. In this case, the plurality of non-folded areas may be spaced apart from each other, and each of the plurality of foldable areas FA may be arranged between the non-folded areas. Each foldable area FA may be folded with respect the folding line FOL, and the folding line FOL may be provided in plural.

Although it is shown in FIG. 1 that the folding line FOL passes through the center of the foldable area FA, and the foldable area FA is line symmetrical with respect to the folding line FOL, the disclosure is not limited thereto. In an embodiment, the folding line FOL may be provided asymmetrically in the foldable area FA.

As shown in FIG. 2, the display apparatus 1 may be folded such that the first surface S1 of the first non-folded area NFA1 faces the first surface S1 of the second non-folded area NFA2 with respect to the folding line FOL. In other words, when the foldable area FA of the display apparatus 1 is bent, the first surface S1 of the first non-folded area NFA1 and the first surface S1 of the second non-folded area NFA2 may be arranged to face each other. Even when the display apparatus 1 is folded, the foldable area FA may extend in a direction crossing a virtual straight line connecting the first non-folded area NFA1 and the second non-folded area NFA2 to each other. Specifically, when the display apparatus 1 is folded, the foldable area FA may extend in the second direction (e.g., the y-axis direction) crossing the virtual straight line (e.g., a straight line parallel to a z-axis direction) connecting the first non-folded area NFA1 and the second non-folded area NFA2 to each other. The foldable area FA may be folded and then unfolded again. That is, the display apparatus 1 may be a foldable display apparatus.

In the specification, the term “folding” means a shape is not fixed but changes from the original shape to a different shape and includes being folded, curved, or bent along at least one predetermined line, that is, the folding line FOL. Accordingly, although FIG. 2 shows the state in which the first surface S1 of the first non-folded area NFA1 and the first surface S1 of the second non-folded area NFA2 are folded to be parallel to each other and to face each other, the disclosure is not limited thereto. In an embodiment, the first surface S1 of the first non-folded area NFA1 and the first surface S1 of the second non-folded area NFA2 may be folded to form a preset angle (e.g., an acute angle or an obtuse angle) with the foldable area FA therebetween.

In addition, although it is shown in FIG. 2 that the display apparatus 1 is folded such that a portion of the first surface S1 and another portion of the first surface S1 face each other, that is, the display apparatus 1 is in-folded, the disclosure is not limited thereto. In an embodiment, the display apparatus 1 may be folded such that a portion of the second surface S2 and another portion of the second surface S2 face each other, that is, the display apparatus 1 may be out-folded. In other words, the display apparatus 1 may be in-folded such that portions of a display surface face each other while the display apparatus 1 is folded, or the display apparatus 1 may be out-folded such that the display surface is exposed to the outside while the display apparatus 1 is folded. Hereinafter, for convenience of description, the case where the display apparatus 1 is in-folded is mainly described.

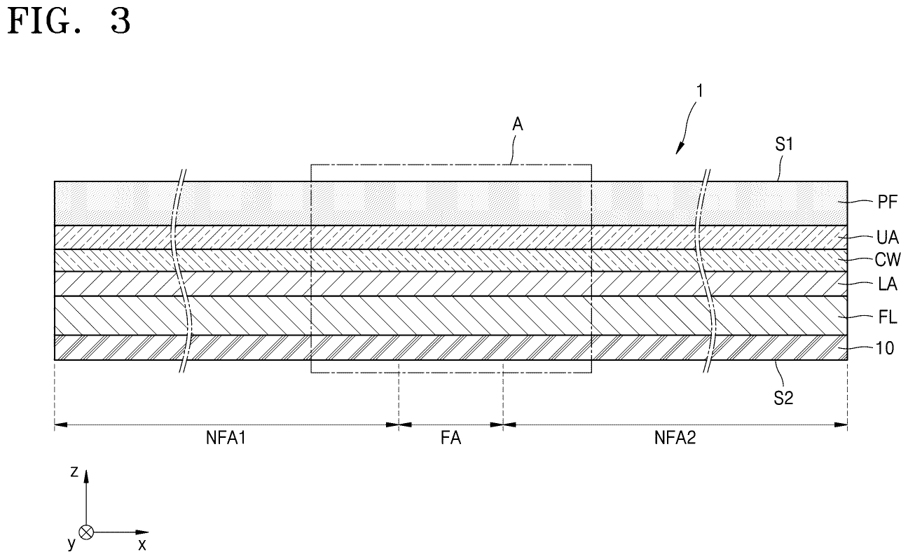

FIG. 3 is a schematic cross-sectional view of the display apparatus 1 of FIG. 1, taken along line I-I′ of FIG. 1. As shown in FIG. 3, the display apparatus 1 may include a display panel 10, a functional layer FL, a cover window CW, and a protective film PF. The display apparatus 1 may further include a lower adhesive layer LA and an upper adhesive layer UA.

The display panel 10 may display images. For this purpose, the display panel 10 may include a plurality of display elements, and the plurality of display elements may emit light. Accordingly, the display panel 10 may display images through light emitted from the plurality of display elements. In an embodiment, the display element may be an organic light-emitting diode including an organic emission layer. In an alternative embodiment, the display element may be a light-emitting diode (“LED”). The size of the light-emitting diode LED may be microscales or nanoscales. In an embodiment, the light-emitting diode may be a micro light-emitting diode. In an alternative embodiment, the light-emitting diode may be a nanorod light-emitting diode. The nanorod light-emitting diode may include gallium nitride (GaN). In an embodiment, a color-converting layer may be disposed on the nano-rod light-emitting diode. The color-converting layer may include quantum dots. In an alternative embodiment, the display element may be a quantum-dot light-emitting diode including a quantum-dot emission layer. In an alternative embodiment, the display element may be an inorganic light-emitting diode including an inorganic semiconductor. Elements of the display panel 10 are described below in detail.

As described above, the display apparatus 1 may include the first non-folded area NFA1, the second non-folded area NFA2, and the foldable area FA. Because the display apparatus 1 includes the display panel 10, it may be understood that the display panel 10 includes the first non-folded area NFA1, the second non-folded area NFA2, and the foldable area FA. Hereinafter, for convenience of description, it is described that the display panel 10 includes the first non-folded area NFA1, the second non-folded area NFA2, and the foldable area FA.

The cover window CW may be disposed on the display panel 10. Specifically, the cover window CW may be disposed on the upper surface (in the +z direction) of the display panel 10. Here, the upper surface of the display panel 10 may be defined as a surface facing a direction in which the display panel 10 displays images. In an embodiment, the cover window CW may be disposed to cover the upper surface of the display panel 10. The cover window CW may protect the upper surface of the display panel 10. In addition, because the cover window CW forms the appearance of the display apparatus 1, the cover window CW may include a plane and a curved surface corresponding to the shape of the display apparatus 1.

The cover window CW may have a relatively high transmittance to transmit light emitted from the display panel 10 and have a thin thickness to reduce the weight of the display apparatus 1. In addition, the cover window CW may have relatively high strength and hardness to protect the display panel 10 from external impacts. The cover window CW may be a flexible window. The cover window CW may protect the display panel 10 while easily bending according to external force without occurrence of cracks or the like.

The cover window CW may include glass, sapphire, or plastic. In an embodiment, the cover window CW may be ultra-thin glass (“UTG®”) whose strength has been strengthened by chemical or thermal strengthening or may be colorless polyimide (“CPI”). The cover window CW may have a structure in which a flexible polymer layer is disposed on one surface of a glass substrate or include only a polymer layer. Images displayed by the display panel 10 may be provided to users through the transparent cover window CW. That is, it may be understood that images displayed by the display apparatus 1 is implemented by the display panel 10.

The functional layer FL may be disposed between the display panel 10 and the cover window CW. Specifically, the functional layer FL may be disposed on the display panel 10, and the cover window CW may be disposed on the functional layer FL. In an embodiment, the functional layer FL may be an optical functional layer which reduces reflectivity of light (e.g., external light) incident toward the display panel 10 from the outside. Accordingly, the functional layer FL may increase color purity of light emitted from the display panel 10. The functional layer FL may include a polarizing film including a phase retarder and a polarizer. The phase retarder may include a λ/2 phase retarder and/or a λ/4 phase retarder.

In another embodiment, the functional layer FL may be a protective layer which protects the display panel 10 from external impacts. Accordingly, the functional layer FL may include a polymer resin. In an embodiment, the functional layer FL may include at least one of polyethersulfone, polyacrylate, polyetherimide, polyethylene naphthalate, polyethylene terephthalate, polyphenylene sulfide, polyimide, polycarbonate, and cellulose acetate propionate. In an alternative embodiment, the functional layer FL may include a material such as glass or quartz.

The protective film PF may be disposed on the cover window CW. The protective film PF may protect the cover window CW and prevent or reduce occurrence of starches on the upper surface (in the +z direction) of the cover window CW. In an embodiment, the protective film PF may include polymer resin. In another embodiment, the protective film PF may include an inorganic material.

In this case, each of the plurality of adhesive layers may be disposed between the elements of the display apparatus 1 to attach one element to another element of the display apparatus 1. Specifically, the upper adhesive layer UA may be disposed between the cover window CW and the protective film PF. The upper adhesive layer UA may attach the protective film PF to the cover window CW. The lower adhesive layer LA may be disposed between the functional layer FL and the cover window CW. The lower adhesive layer LA may attach the cover window CW to the functional layer FL. Specifically, the lower adhesive layer LA may attach the cover window CW to the display panel 10 through the functional layer FL. Although not shown in FIG. 3, the adhesive layer may be also disposed between the display panel 10 and the functional layer FL. The adhesive layer may attach the functional layer FL to the display panel 10. The plurality of adhesive layers may include, e.g., an adhesive member such as an optical clear adhesive (“OCA”).

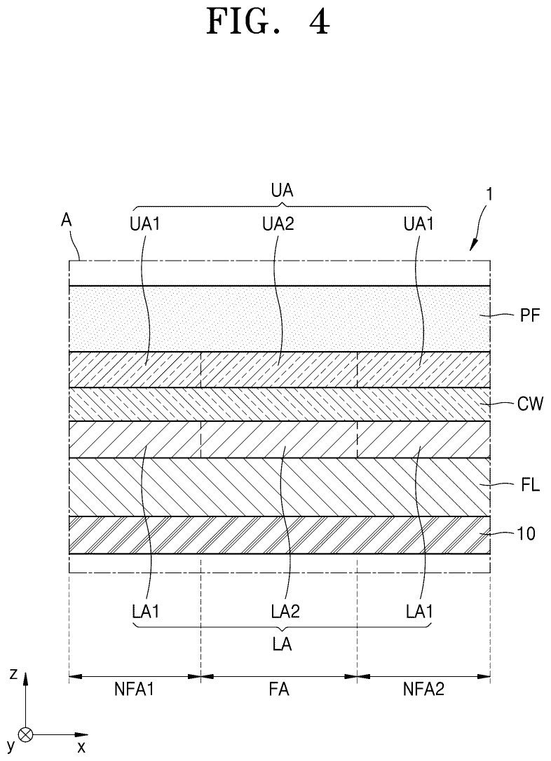

FIG. 4 is a schematic enlarged cross-sectional view of a region A of the display apparatus 1 of FIG. 3. As shown in FIG. 4, the lower adhesive layer LA may include a first lower adhesive layer LA1 and a second lower adhesive layer LA2. The upper adhesive layer UA may include a first upper adhesive layer UA1 and a second upper adhesive layer UA2.

The first lower adhesive layer LA1 may be disposed in the non-folded areas, and the second lower adhesive layer LA2 may be disposed in the foldable area FA. Specifically, the first lower adhesive layer LA1 may be disposed in the first non-folded area NFA1 and the second non-folded area NFA2. That is, the first lower adhesive layer LA1 may overlap the first non-folded area NFA1 and the second non-folded area NFA2, and the second lower adhesive layer LA2 may overlap the foldable area FA. Similarly, the first upper adhesive layer UA1 may be disposed in the non-folded areas, and the second upper adhesive layer UA2 may be disposed in the foldable area FA. Specifically, the first upper adhesive layer UA1 may be disposed in the first non-folded area NFA1 and the second non-folded area NFA2. That is, the first upper adhesive layer UA1 may overlap the first non-folded area NFA1 and the second non-folded area NFA2, and the second upper adhesive layer UA2 may overlap the foldable area FA.

The impact resistance of the first lower adhesive layer LA1 and the first upper adhesive layer UA1 may be superior to the impact resistance of the second lower adhesive layer LA2 and the second upper adhesive layer UA2. Accordingly, even when external impacts are applied to the display apparatus 1, the display apparatus 1 may not be easily damaged. The creep recovery of the second lower adhesive layer LA2 and the second upper adhesive layer UA2 may be superior to the creep recovery of the first lower adhesive layer LA1 and the first upper adhesive layer UA1. Accordingly, even though the display apparatus 1 is repeatedly folded in the foldable area FA in which the second lower adhesive layer LA2 and the second upper adhesive layer UA2 are arranged, the display apparatus 1 may not be easily damaged.

The first lower adhesive layer LA1 and the first upper adhesive layer UAL may be cured products of a first adhesive composition. That is, the first adhesive composition includes oligomers and monomers, and the first lower adhesive layer LA1 or the first upper adhesive layer UAL may be formed by polymerizing these oligomers and monomers. The second lower adhesive layer LA2 and the second upper adhesive layer UA2 may be cured products of a second adhesive composition. Similar to the first adhesive composition, the second adhesive composition includes oligomers and monomers, and the second lower adhesive layer LA2 or the second upper adhesive layer UA2 may be formed by polymerizing these oligomers and monomers. The second adhesive composition includes the same materials as those configuring the first adhesive composition, but the contents (e.g., weight percentages) of these materials in the second adhesive composition may be different from the contents of these materials in the first adhesive composition. A method of manufacturing the first adhesive composition, the second adhesive composition, the lower adhesive layer LA, and the upper adhesive layer UA is described below in detail.

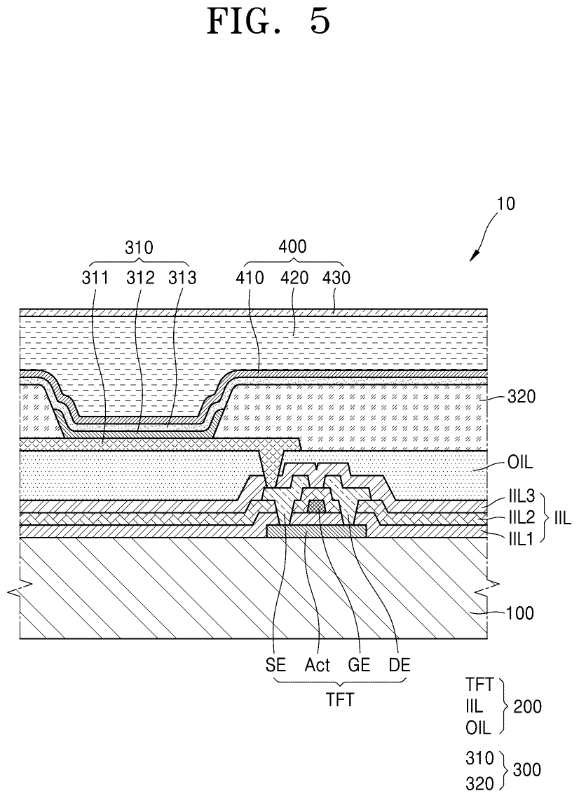

FIG. 5 is a schematic cross-sectional view of a portion of the display panel 10 included in the display apparatus 1 of FIG. 3. As shown in FIG. 5, the display panel 10 may include a substrate 100, a circuit layer 200, a display element layer 300, and an encapsulation layer 400.

The substrate 100 may include glass, metal, or polymer resin. The substrate 100 may be flexible or bendable. In this case, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide (SiOₓ), silicon nitride (SiNₓ), silicon oxynitride (SiOₓN_{y}), or the like) therebetween. However, various modifications may be made.

The circuit layer 200 may be disposed on the substrate 100. The circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first inter-insulating layer IIL2, and a second inter-insulating layer IIL3.

The semiconductor layer Act may be disposed on the substrate 100. The semiconductor layer Act may include polycrystalline silicon. In an alternative embodiment, the semiconductor layer Act may include amorphous silicon, an oxide semiconductor, or an organic semiconductor. In an embodiment, the semiconductor layer Act may include a channel region, a drain region, and a source region, the drain region and the source region being on two opposite sides of the channel region.

The gate insulating layer IIL1 may be disposed on the semiconductor layer Act and the substrate 100. The gate insulating layer IIL1 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

The gate electrode GE may be disposed on the gate insulating layer IIL1. That is, because the gate insulating layer IIL1 is disposed between the semiconductor layer Act and the gate electrode GE, insulation between the semiconductor layer Act and the gate electrode GE may be secured. The gate electrode GE may overlap the channel region of the semiconductor layer Act. The gate electrode GE may include a low-resistance metal material. In an embodiment, the gate electrode GE may include a conductive material including molybdenum (Mo), aluminum (Al), copper (Cu), and titanium (Ti) and include a single layer or a multi-layered structure including the above conductive materials.

The first inter-insulating layer IIL2 may be disposed on the gate electrode GE and the gate insulating layer IIL1. The first inter-insulating layer IIL2 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOₓ).

The source electrode SE and the drain electrode DE may be disposed on the first inter-insulating layer IIL2. Each of the source electrode SE and the drain electrode DE may be connected to the semiconductor layer Act through a contact hole defined in the gate insulating layer IIL1 and the first inter-insulating layer IIL2. At least one of the source electrode SE and the drain electrode DE may include a conductive material including molybdenum (Mo), aluminum (Al), copper (Cu), and titanium (Ti) and include a single layer or a multi-layered structure including the above conductive materials. In an embodiment, at least one of the source electrode SE and the drain electrode DE may have a multi-layered structure of Ti/Al/Ti.

The second inter-insulating layer IIL3 may be disposed on the source electrode SE, the drain electrode DE, and the first inter-insulating layer IIL2. The second inter-insulating layer IIL3 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOₓ).

The organic insulating layer OIL may be disposed on the second inter-insulating layer IIL3. The organic insulating layer OIL may generally planarize the upper portion of the circuit layer 200. The organic insulating layer OIL may include, e.g., acryl, benzocyclobutene (“BCB”), or hexamethyldisiloxane (“HMDSO”). Although it is shown in FIG. 5 that the organic insulating layer OIL is a single layer, the organic insulating layer OIL may be a multi-layer. However, various modifications may be made.

The display element layer 300 may be disposed on the circuit layer 200. The display element layer 300 may include a display element 310 and a pixel-defining layer 320. The display element 310 may be electrically connected to the transistor TFT. The display element 310 may be an organic light-emitting diode including a pixel electrode 311, an opposite electrode 313, and an intermediate layer 312, where the intermediate layer 312 is disposed between the pixel electrode 311 and the opposite electrode 313 and includes an emission layer. When the display element 310 is electrically connected to the transistor TFT, it may be understood that the pixel electrode 311 of the organic light-emitting diode is electrically connected to the transistor TFT.

The pixel electrode 311 may be electrically connected to the transistor TFT by being in contact with one of the source electrode SE and the drain electrode DE through a contact hole defined in the second inter-insulating layer IIL3 and the organic insulating layer OIL. The pixel electrode 311 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or any combinations thereof. In another embodiment, the pixel electrode 311 may further include a layer on/under the reflective layer, the layer including ITO, IZO, ZnO, or In₂O₃.

The pixel-defining layer 320 may cover the edges of the pixel electrode 311. A pixel opening may be defined in the pixel-defining layer, and the pixel opening may overlap the pixel electrode 311. The pixel opening may define an emission area of light emitted from the display element 310. The pixel-defining layer 320 may include an organic insulating material and/or an inorganic insulating material. In an embodiment, the pixel-defining layer 320 may include a light-blocking material.

The intermediate layer 312 may be disposed on the pixel electrode 311 and the pixel-defining layer 320. The intermediate layer 312 may include a low-molecular weight material or a polymer material. In the case where the intermediate layer 312 includes a relatively low molecular weight material, the intermediate layer 312 may have a structure in which a hole injection layer (“HIL”), a hole transport layer (“HTL”), an emission layer (“EML”), an electron transport layer (“ETL”), an electron injection layer (“EIL”), etc. are stacked in a single or composite configuration. The intermediate layer 312 may be formed by vacuum deposition. In the case where the intermediate layer 312 includes a polymer material, the intermediate layer 312 may have a structure including an HTL and an EML. In this case, the HTL may include poly (3, 4-ethylenedioxythiophene) (“PEDOT”), and the EML may include a polymer material such as a polyphenylene vinylene (“PPV”)-based material and a polyfluorene-based material. The intermediate layer 312 may be formed by screen printing, inkjet printing, laser induced thermal imaging (“LITI”), or the like. The intermediate layer 312 is not necessarily limited thereto but may have various structures. In addition, the intermediate layer 312 may include a layer, which is one body over the plurality of pixel electrodes 311, or include a layer patterned to correspond to each of the plurality of pixel electrodes 311.

The opposite electrode 313 may be disposed on the intermediate layer 312 and the pixel-defining layer 320. The opposite electrode 313 may be unitary over a plurality of organic light-emitting diodes to correspond to the plurality of pixel electrodes 311. The opposite electrode 313 may include a light-transmissive conductive layer including ITO, In₂O₃, or IZO, and include a semi-transmissive layer including metal such as aluminum (Al) or silver (Ag). In an embodiment, the opposite electrode 313 may be a semi-transmissive layer including magnesium (Mg) and silver (Ag).

Because the display element 310 may be easily damaged by external moisture, oxygen, or the like, an encapsulation layer 400 may protect the display element 310 by covering the display element 310. As shown in FIG. 5, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include silicon oxide (SiO_{X}), silicon nitride (SiN_{X}), and/or silicon oxynitride (SiO_{X}N_{Y}). When desired, other layers including a capping layer may be disposed between the first inorganic encapsulation layer 410 and the opposite electrode 313. Because the first inorganic encapsulation layer 410 is formed along a structure thereunder, the upper surface of the first inorganic encapsulation layer 410 may not be flat as shown in FIG. 5. The organic encapsulation layer 420 may cover the first inorganic encapsulation layer 410 and, unlike the first inorganic encapsulation layer 410, the upper surface of the organic encapsulation layer 420 may be approximately flat. The organic encapsulation layer 420 may include at least one material among polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420 and may include silicon oxide (SiO_{X}), silicon nitride (SiN_{X}), and/or silicon oxynitride (SiO_{X}N_{Y}).

Because the encapsulation layer 400 includes the first inorganic encapsulation layer 410, the organic encapsulation layer 420, and the second inorganic encapsulation layer 430, even when cracks occur inside the encapsulation layer 400, the cracks may not be connected between the first inorganic encapsulation layer 410 and the organic encapsulation layer 420 or between the organic encapsulation layer 420 and the second inorganic encapsulation layer 430 through the above multi-layered structure. With this configuration, forming of a path through which external moisture or oxygen penetrates the inside of a display panel 10 may be prevented or reduced.

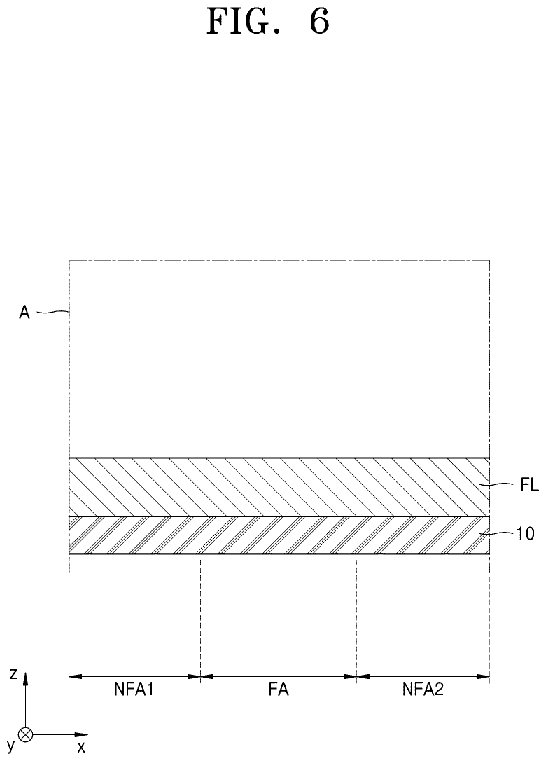

FIGS. 6 to 12 are schematic cross-sectional views to explain a method of manufacturing a display apparatus. Specifically, FIGS. 6 to 12 are schematic cross-sectional views showing a portion of the process of manufacturing the display apparatus 1 of FIG. 3. In FIGS. 6 to 12, for convenience of description, a method of manufacturing a display apparatus is described based on a portion of the display apparatus 1 of FIG. 3. Hereinafter, in describing the method of manufacturing a display apparatus in an embodiment with reference to FIGS. 6 to 12, because the same reference numerals as those in FIGS. 1 to 5 denote the same elements, repeated descriptions thereof are omitted.

First, as shown in FIG. 6, the display panel 10 may be prepared. As described above, the display panel 10 may include the first non-folded area NFA1, the second non-folded area NFA2, and the foldable area FA. The foldable area FA may be disposed between the first non-folded area NFA1 and the second non-folded area NFA2. The display panel 10 may be in a state where a functional layer FL is attached to the display panel 10. Specifically, the functional layer FL may be attached to one surface of the display panel 10. The functional layer FL may be attached to one surface of the display panel 10 using an adhesive member.

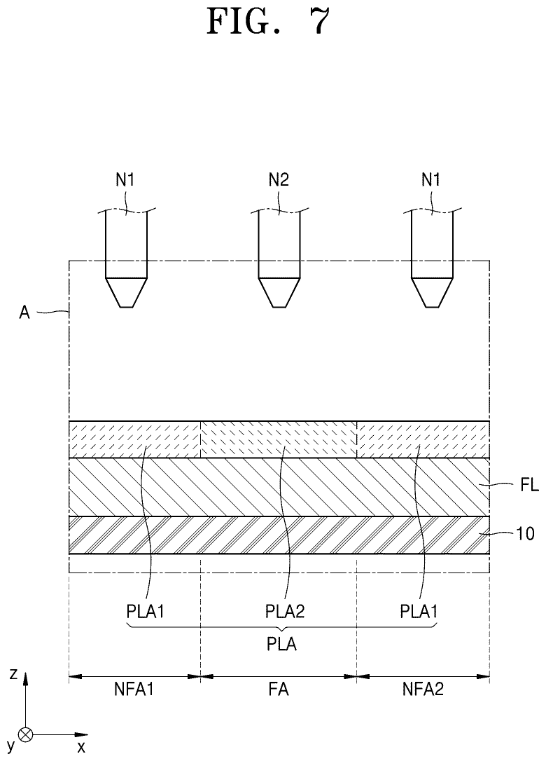

Subsequently, as shown in FIG. 7, a preliminary lower adhesive layer PLA may be formed on the display panel 10. Specifically, because the functional layer FL is attached to one surface of the display panel 10, the preliminary lower adhesive layer PLA may be formed on the functional layer FL attached to the display panel 10. The preliminary lower adhesive layer PLA may include a preliminary first lower adhesive layer PLA1 and a preliminary second lower adhesive layer PLA2.

In an embodiment, a first adhesive composition may be coated on a portion of the functional layer FL overlapping the first non-folded area NFA1 and the second non-folded area NFA2. Accordingly, the preliminary first lower adhesive layer PLA1 overlapping the first non-folded area NFA1 and the second non-folded area NFA2 may be formed. That is, the preliminary first lower adhesive layer PLA1 may be the first adhesive composition coated on the cover window CW or the functional layer FL to attach the cover window CW to the functional layer FL. Together, a second adhesive composition may be coated on another portion of the functional layer FL overlapping the foldable area FA. Accordingly, the preliminary second lower adhesive layer PLA2 overlapping the foldable area FA may be formed. That is, the preliminary second lower adhesive layer PLA2 may be the second adhesive composition coated on the cover window CW or the functional layer FL to attach the cover window CW to the functional layer FL.

The coating of the first adhesive composition and the coating of the second adhesive composition may be performed simultaneously. That is, the first adhesive composition and the second adhesive composition may be coated simultaneously. As shown in FIG. 7, the first adhesive composition may be coated on a portion of the functional layer FL overlapping the first non-folded area NFA1 and the second non-folded area NFA2 using a first nozzle N1, and the second adhesive composition may be coated on another portion of the functional layer FL overlapping the foldable area FA using a second nozzle N2. In other words, the first adhesive composition and the second adhesive composition may be simultaneously coated on the functional layer FL using the first nozzle N1 and the second nozzle N2.

Generally, in the case where one of the first adhesive composition and the second adhesive composition is coated first, the adhesive composition coated first spread up to a region other than a preset region. Accordingly, the characteristics of the adhesive layer depending on the position of the adhesive layer may be different from the preset characteristics. In an alternative embodiment, in the case where one of the first adhesive composition and the second adhesive composition is coated first and then the other of the first adhesive composition and the adhesive composition coated first is cured, and then the second adhesive composition is coated, the end of the cured adhesive composition coated first forms a slope. Because the other adhesive composition is coated on the slope, a step difference is formed at a boundary between a portion of the adhesive layer formed from the first adhesive composition and a portion of the adhesive layer formed from the second adhesive composition. In contrast, in the method of manufacturing the display apparatus in an embodiment, because the coating of the first adhesive composition and the coating of the second adhesive composition are simultaneously performed, the adhesive composition coated first may not spread up to a region other than the preset region, and the end of the cured adhesive composition coated first may not form a slope. Accordingly, possibility of defect occurrence during the process of manufacturing the display apparatus 1 may be reduced.

As described above, the second adhesive composition includes the same materials as those configuring the first adhesive composition, but the contents of these materials in the second adhesive composition may be different from the contents of these materials in the first adhesive composition. Specifically, each of the first adhesive composition and the second adhesive composition may include a first crosslinkable monomer including or consisting of a hydroxyl group, a second crosslinkable monomer non-including a hydroxyl group, a third crosslinkable monomer including or consisting of a heterocyclic group at the end, a fourth crosslinkable monomer including or consisting of an ethylene glycol group, and an oligomer.

The first crosslinkable monomer, the third crosslinkable monomer, and the fourth crosslinkable monomer reduce the viscosity of the adhesive composition. Because the second crosslinkable monomer has a relatively low glass transition temperature, the second crosslinkable monomer improves the folding characteristics of the display apparatus 1 to which an adhesive layer formed from the adhesive composition including or consisting of he second crosslinkable monomer is applied, but reduces the impact resistance of the display apparatus 1. Accordingly, an adhesive layer formed from an adhesive composition with a relatively high content of the second crosslinkable monomer improves the folding characteristics of the display apparatus 1, and an adhesive layer formed from an adhesive composition with a relatively low content of the second crosslinkable monomer improves the impact resistance of the display apparatus 1.

In an embodiment, the first crosslinkable monomer including or consisting of a hydroxyl group may be an acrylate-based monomer. In an embodiment, the first crosslinking monomer may include at least one of 4-hydroxybutyl (meth)acrylate, 2-hydroxypropyl (meth)acrylate, 2-hydroxyethyl (meth)acrylate, and di hydroxyhexyl (meth)acrylate. In the specification, (meth)acrylate denotes acrylate or methacrylate.

In an embodiment, the second crosslinkable monomer non-including a hydroxyl group may be an acrylate-based monomer. In an embodiment, the second crosslinkable monomer may include at least one of 2-ethylhexyl (meth)acrylate, ethyl (meth)acrylate, methyl (meth)acrylate, n-propyl (meth)acrylate, isopropyl (meth)acrylate, pentyl (meth)acrylate, n-octyl (meth)acrylate, isooctyl (meth)acrylate, isononyl (meth)acrylate, n-butyl (meth)acrylate, isobutyl (meth)acrylate, n-hexyl (meth)acrylate, n-nonyl (meth)acrylate, isoamyl (meth)acrylate, n-decyl (meth)acrylate, isodecyl (meth)acrylate, dodecyl (meth)acrylate, isobornyl (meth)acrylate, cyclohexyl (meth)acrylate, phenyl (meth)acrylate, benzyl (meth)acrylate, isostearyl (meth)acrylate, and 2-methylbutyl (meth)acrylate.

In an embodiment, the third crosslinkable monomer including or consisting of a heterocyclic group at the terminal may be an acrylate-based monomer. The heterocyclic group may be a C₁-C₁₀ heterocycloalkyl group or a C₁-C₁₀ heterocycloalkenyl group, for example. A C₁-C₁₀ heterocycloalkyl group refers to a monovalent cyclic group having 1 to 10 carbon atoms, which, in addition to carbon atoms, further includes or consists of at least one hetero atom as a ring-forming atom. The C₁-C₁₀ heterocycloalkenyl group is a monovalent cyclic group with 1 to 10 carbon atoms, which, in addition to carbon atoms, further includes or consists of at least one hetero atom as a ring-forming atom, and has at least one double bond in the ring.

In an embodiment, the third crosslinkable monomer including or consisting of a heterocyclic group at the terminal may include at least one of tetrahydrofurfuryl (meth)acrylate, (tetrahydro-2H-pyran-2-yl)methyl (meth)acrylate, [(oxetan-2-yl)methyl (meth)acrylate], (oxetan-2-yl)methyl (meth)acrylate], (2-oxa-bicyclo[2.2.2]octan-6-yl)methyl (meth)acrylate, and (7-oxa-bicyclo[2.2.1]heptan-2-yl)methyl (meth)acrylate.

In an embodiment, the fourth crosslinkable monomer including or consisting of an ethylene glycol group may be an acrylate-based monomer. In an embodiment, the fourth crosslinkable monomer including or consisting of an ethylene glycol group may include at least one of di(ethylene glycol) 2-ethylhexyl ether acrylate and ethylene glycol (meth)acrylate.

In an embodiment, an oligomer may be an acrylate-based oligomer. In an embodiment, the oligomer may include urethane (meth)acrylate oligomer. The urethane (meth)acrylate oligomer may include a photocurable compound including or consisting of at least one (meth)acryloyl group having a urethane bond. The urethane (meth)acrylate oligomer may include at least one of acrylate having a urethane bond, urethane acrylate having a polycarbonate skeleton, and urethane acrylate having a polyether skeleton.

In an embodiment, each of the first adhesive composition and the second adhesive composition may be a urethane acrylate oligomer and include at least one of UF-C051 (manufactured by Kyoeisha Chemical Co., Ltd.), UF-C052 (manufactured by Kyoeisha Chemical Co., Ltd.), and UN-6304 (manufactured by Negami Industrial Co., Ltd.). UF-C051 may be a urethane acrylate with a molecular weight of 35,000 and a glass transition temperature of −43 degrees Celsius (° C.), and UF-C052 may be a urethane acrylate with a molecular weight of 10,000 and a glass transition temperature of −44° C. UN-6304 may be a urethane acrylate with a molecular weight of 13,000 and a glass transition temperature of −74° C. However, the disclosure is not limited thereto. The adhesive composition including or consisting of an acrylate-based oligomer may show relatively low viscosity characteristics that may be coated by methods such as inkjet printing or dispensing coating.

The content of the second crosslinkable monomer included in the first adhesive composition may be less than the content of the second crosslinkable monomer included in the second adhesive composition. Specifically, the content of the second crosslinkable monomer contained in the first adhesive composition based on the total weight of monomers and oligomers of the first adhesive composition is less than the content of the second crosslinkable monomer contained in the second adhesive composition based on the total weight of monomers and oligomers of the second adhesive composition. As described above, because the second crosslinkable monomer has a relatively low glass transition temperature, the second crosslinkable monomer improves the folding characteristics of the display apparatus 1 to which an adhesive layer formed from the adhesive composition including or consisting of he second crosslinkable monomer is applied, but may reduce the impact resistance of the display apparatus 1. Accordingly, the portion of the adhesive layer formed from the first adhesive composition with a relatively low content of the second crosslinkable monomer improves the impact resistance, and the portion of the adhesive layer formed from the second adhesive composition with a relatively high content of the second crosslinkable monomer improves the folding characteristics. The expression ‘based on the total weight of monomers and oligomers of the first adhesive composition’ means that the total weight of monomers and oligomers of the first adhesive composition is considered to be 100 wt %. That is, the content of the second crosslinkable monomer contained in the first adhesive composition based on the total weight of monomers and oligomers of the first adhesive composition means the weight percentage of the second crosslinkable monomer contained in the first adhesive composition when the total weight of monomers and oligomers of the first adhesive composition is considered to be 100 wt %. The expression ‘based on the total weight of monomers and oligomers of the second adhesive composition’ means that the total weight of monomers and oligomers of the second adhesive composition is considered to be 100 wt %. That is, the content of the second crosslinkable monomer contained in the second adhesive composition based on the total weight of monomers and oligomers of the second adhesive composition means the weight percentage of the second crosslinkable monomer contained in the second adhesive composition when the total weight of monomers and oligomers of the second adhesive composition is considered to be 100 wt %.

Specifically, a difference between the content of the second crosslinkable monomer contained in the first adhesive composition based on the total weight of monomers and oligomers of the first adhesive composition, and the content of the second crosslinkable monomer contained in the second adhesive composition based on the total weight of monomers and oligomers of the second adhesive composition may be about 5 wt % to about 45 wt %. That is, the content of the second crosslinkable monomer included in the first adhesive composition may be less than the content of the second crosslinkable monomer included in the second adhesive composition. In the case where the difference between the content of the second crosslinkable monomer contained in the first adhesive composition and the content of the second crosslinkable monomer contained in the second adhesive composition is less than 5 wt %, the portion of the adhesive layer formed from the first adhesive composition may have a little effect of improving the impact resistance. In the case where the difference between the content of the second crosslinkable monomer contained in the first adhesive composition and the content of the second crosslinkable monomer contained in the second adhesive composition exceeds 45 wt %, a boundary between the portion of the adhesive layer formed from the first adhesive composition and the portion of the adhesive layer formed from the second adhesive composition may be viewed.

Accordingly, the content of the first crosslinkable monomer included in the first adhesive composition may be greater than the content of the first crosslinkable monomer included in the second adhesive composition, and the content of the third crosslinkable monomer included in the first adhesive composition may be greater than the content of the third crosslinkable monomer included in the second adhesive composition. The content of the fourth crosslinkable monomer included in the first adhesive composition may be less than the content of the fourth crosslinkable monomer included in the second adhesive composition.

In an embodiment, each of the first adhesive composition and the second adhesive composition may further include a silane coupling agent and a photoinitiator. The photoinitiator may be any compound that causes the polymerization reaction to be initiated by light, such as ultraviolet (“UV”) light. In an embodiment, a silane coupling agent may include at least one of γ-glycidoxypropyltriethoxysilane, γ-glycidoxypropyltrimethoxysilane, γ-glycidoxypropylmethyldiethoxysilane, γ-glycidoxypropylmethyldimethoxysilane, 3-chloropropyltrimethoxysilane, 3-chloropropyltriethoxysilane, 2-chloroethyltrimethoxysilane, 2-chloroethyltriethoxysilane, γ-methacryloxypropyl trimethoxysilane, γ-meth acryloxypropyl methyldimethoxysilane, and γ-methacryloxypropyl dimethylmethoxysilane. In an embodiment, a photoinitiator may include at least one of 4-acryloxybenzophenone, 2,2-dimethoxy-2-phenylacetophenone, 2-hydroxy-2-methyl-1-phenyl-1-propan-1-one, ethyl (2,4,6-trimethylbenzoyl)phenyl phosphinate, and bisacylphosphine oxide.

In an embodiment, a difference between a surface tension of the first adhesive composition and a surface tension of the second adhesive composition at room temperature may be about 0.1 millinewton per meter (mN/m) to about 1 mN/m. Specifically, a difference between the dynamic surface tension of the first adhesive composition and the dynamic surface tension of the second adhesive composition may be about 0.1 mN/m to about 1 mN/m. Also, a difference between the static surface tension of the first adhesive composition and the static surface tension of the second adhesive composition may be about 0.1 mN/m to about 1 mN/m. In the case where the difference between the surface tension of the first adhesive composition and the surface tension of the second adhesive composition exceeds 1 mN/m, when the first adhesive composition and the second adhesive composition are coated simultaneously, the adhesive composition with relatively low surface tension may move below the adhesive composition with relatively high surface tension among the first adhesive composition and the second adhesive composition.

In an embodiment, a difference between the predetermined gravity of the first adhesive composition and the predetermined gravity of the second adhesive composition may be about 0.1 or less. In the case where the difference between the predetermined gravity of the first adhesive composition and the predetermined gravity of the second adhesive composition exceeds 0.1, when the first adhesive composition and the second adhesive composition are coated simultaneously, the adhesive composition with the relatively high predetermined gravity may move below the adhesive composition with the relatively low predetermined gravity among the first adhesive composition and the second adhesive composition. Because methods of measuring a dynamic surface tension, a static surface tension, or predetermined gravity of an adhesive composition are common in manufacturing display apparatuses, detailed descriptions thereof are omitted.

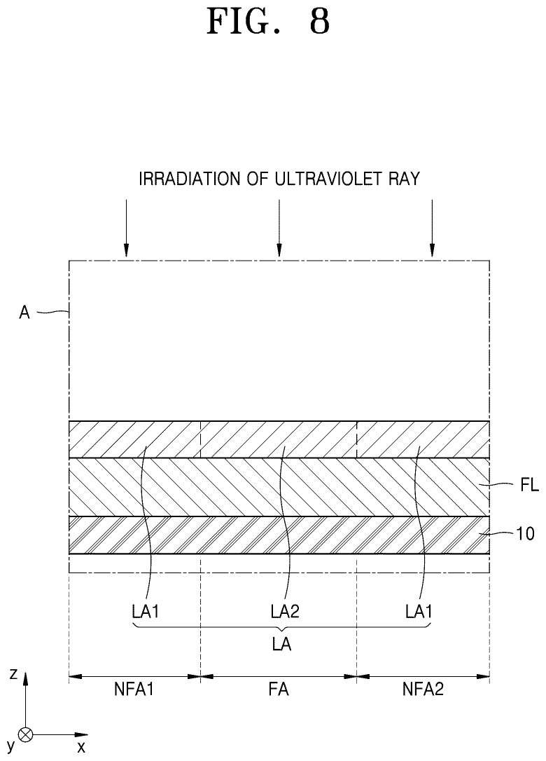

Subsequently, as shown in FIG. 8, the lower adhesive layer LA including the first lower adhesive layer LA1 and the second lower adhesive layer LA2 may be formed by irradiating a UV ray to the preliminary lower adhesive layer PLA. That is, the first lower adhesive layer LA1 may be a cured preliminary first lower adhesive layer PLA1, and the second lower adhesive layer LA2 may be a cured preliminary second lower adhesive layer PLA2. Specifically, UV rays having a light intensity of about 100 millijoules per square centimeter (mJ/cm²) to about 1000 mJ/cm² may be irradiated to the preliminary lower adhesive layer PLA. UV rays with a wavelength of about 300 nanometers (nm) to about 400 nm may be used for photocuring. An LED or metal halide may be used as a UV source. By irradiating UV rays to the preliminary lower adhesive layer PLA, the preliminary lower adhesive layer PLA may be photocured.

In an embodiment, a modulus of the first lower adhesive layer LA1 at room temperature may be 1.5 megapascal (MPa) or more, and a modulus of the second lower adhesive layer LA2 at room temperature may be about 0.03 MPa to about 1.5 MPa. Accordingly, the impact resistance of the first lower adhesive layer LA1 may be superior to that of the second lower adhesive layer LA2. In an embodiment, a difference between the refractive index of the first lower adhesive layer LA1 and the refractive index of the second lower adhesive layer LA2 may be about 0.1 or less. In the case where a difference between the refractive index of the first lower adhesive layer LA1 and the refractive index of the second lower adhesive layer LA2 exceeds 0.1, the boundary between the first lower adhesive layer LA1 and the second lower adhesive layer LA2 may be viewed.

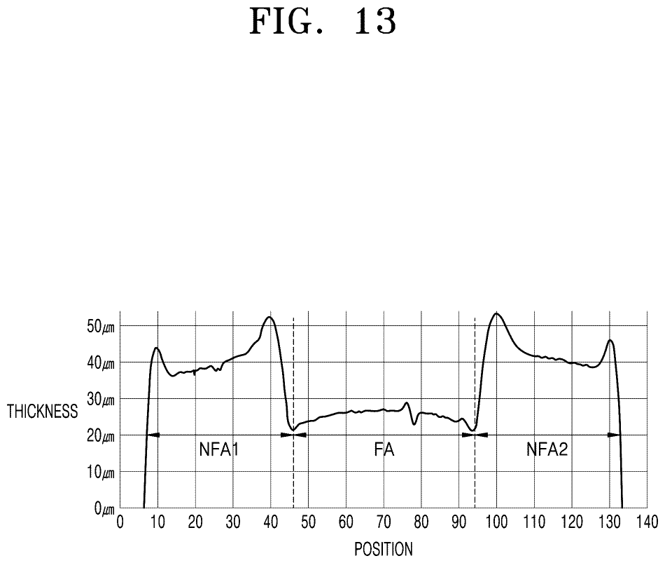

Generally, in the case where the second adhesive composition includes materials different from those configuring the first adhesive composition, when the first adhesive composition and the second adhesive composition are coated simultaneously, the first adhesive composition and the second adhesive composition are pushed against each other. Accordingly, the adhesive layer formed from the adhesive compositions is not flat. In an embodiment, as shown in FIG. 13 which is a graph showing a thickness profile of an adhesive layer included in a display apparatus manufactured by a method of manufacturing a display apparatus according to a comparative example, the thickness of a portion of the adhesive layer overlapping the foldable area FA is less than the thickness of a portion of the adhesive layer overlapping the first non-folded area NFA1 and the second non-folded area NFA2. In addition, the adhesive layer is raised near the boundary between the portion of the adhesive layer overlapping the first non-folded area NFA1 and the second non-folded area NFA2 and the portion of the adhesive layer overlapping the foldable area FA. In contrast, in the method of manufacturing the display apparatus in an embodiment, because the second adhesive composition material includes the same materials as those configuring the first adhesive composition, when the first adhesive composition and the second adhesive composition are simultaneously coated, the first adhesive composition and the second adhesive composition may not be pushed against each other.

Table 1 shows contents of monomers and an oligomer included in the first adhesive composition and the second adhesive composition used in the manufacturing method. The content of each of the first to fourth crosslinkable monomers and oligomers in the first adhesive composition may be based on the total weight of the first to fourth crosslinkable monomers and oligomers contained in the first adhesive composition. The content of each of the first to fourth crosslinkable monomers and oligomers in the second adhesive composition may be based on the total weight of the first to fourth crosslinkable monomers and oligomers contained in the second adhesive composition.

TABLE 1

| | | | Second |
|---|---|---|---|
| | | First adhesive | adhesive |
| | | composition | composition |
| | | (wt %) | (wt %) |
| First | 4-hydroxybutyl acrylate | 50 | 10 |
| crosslinkable | | | |
| monomer | | | |
| Second | 2-ethylhexyl acrylate | 10 | 50 |
| crosslinkable | | | |
| monomer | | | |
| Third | Tetrahydrofurfuryl | 20 | 15 |
| crosslinkable | acrylate | | |
| monomer | | | |
| Fourth | Di(ethylene glycol) | 7 | 12 |
| crosslinkable | 2-ethylhexyl ether | | |
| monomer | (meth)acrylate | | |
| oligomer | UF-C051 | 3 | 3 |
| | UF-C052 | 3 | 3 |
| | UN-6304 | 7 | 7 |

As shown in Table 1, each of the first adhesive composition and the second adhesive composition includes a first crosslinkable monomer to a fourth crosslinkable monomer and an oligomer. Specifically, each of the first adhesive composition and the second adhesive composition includes 4-hydroxybutyl acrylate, 2-ethylhexyl acrylate, tetrahydrofurfuryl acrylate, and di(ethylene glycol) 2-ethylhexyl ether (meth)acrylate, UF-C051, UF-C052, and UN-6304.

The content of the second crosslinkable monomer included in the first adhesive composition is less than the content of the second crosslinkable monomer included in the second adhesive composition. Specifically, the first adhesive composition includes or consists of about 10 wt % of 2-ethylhexyl acrylate, and the second adhesive composition includes or consists of about 50 wt % of 2-ethylhexyl acrylate. That is, the difference between the content of the second crosslinkable monomer contained in the first adhesive composition based on the total weight of the first crosslinkable monomer, second crosslinkable monomer, third crosslinkable monomer, fourth crosslinkable monomer, and oligomer contained in the first adhesive composition, and the content of the second crosslinkable monomer contained in the second adhesive composition based on the total weight of the first cross-linkable monomer, second cross-linkable monomer, third cross-linkable monomer, fourth cross-linkable monomer, and oligomer contained in the second adhesive composition is about 5 wt % to about 45 wt %.

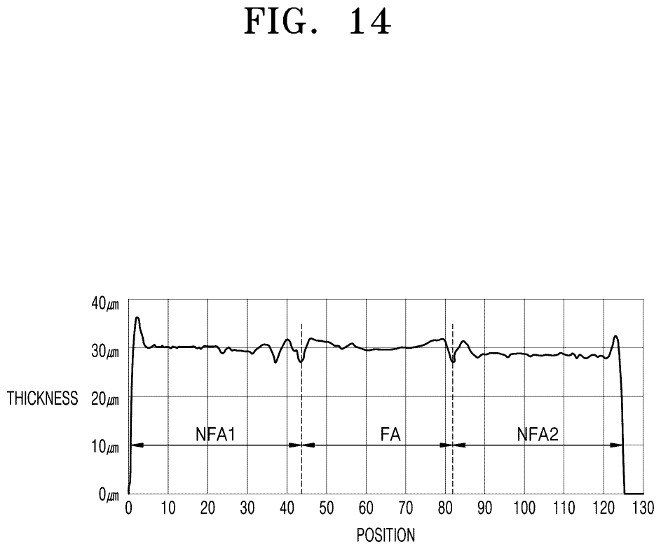

A dynamic surface tension of the first adhesive composition is about 28 mN/m, and a dynamic surface tension of the second adhesive composition is about 29 mN/m. A static surface tension of the first adhesive composition is about 28 mN/m, and a static surface tension of the second adhesive composition is about 29 mN/m. A predetermined gravity of the first adhesive composition is about 1.05, and a predetermined gravity of the second adhesive composition is about 0.98. A modulus of the first lower adhesive layer formed from the first adhesive composition is about 2.0 MPa, and a modulus of the second lower adhesive layer formed from the second adhesive composition is about 0.5 MPa. A refractive index of the first lower adhesive layer formed from the first adhesive composition is about 1.50, and a refractive index of the second lower adhesive layer formed from the second adhesive composition is about 1.45. As shown in FIG. 14 which is a graph showing a thickness profile of the adhesive layer included in the display apparatus 1 manufactured by the method of manufacturing a display apparatus in an embodiment, the adhesive layer formed from the adhesive compositions may be flat. That is, possibility of defect occurrence during the process of manufacturing the display apparatus 1 may be reduced.

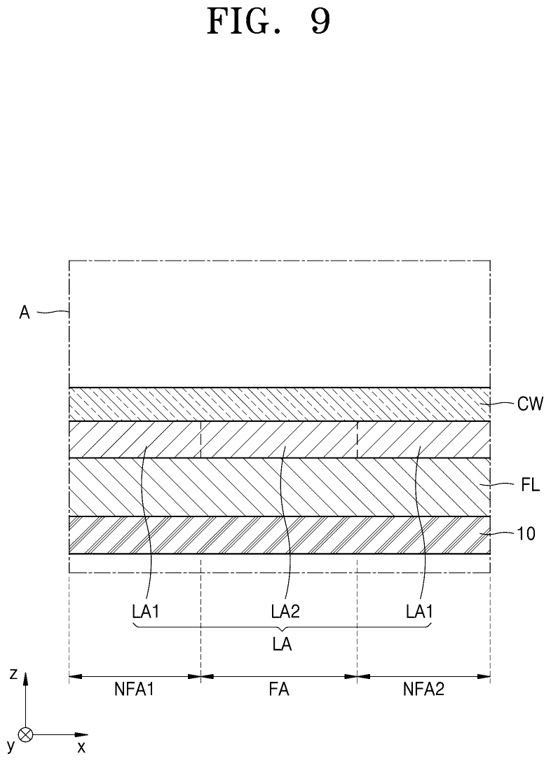

As shown in FIG. 9, the cover window CW may be attached to the functional layer FL. Specifically, the cover window CW may be attached to the functional layer FL using the lower adhesive layer LA formed on the functional layer FL.

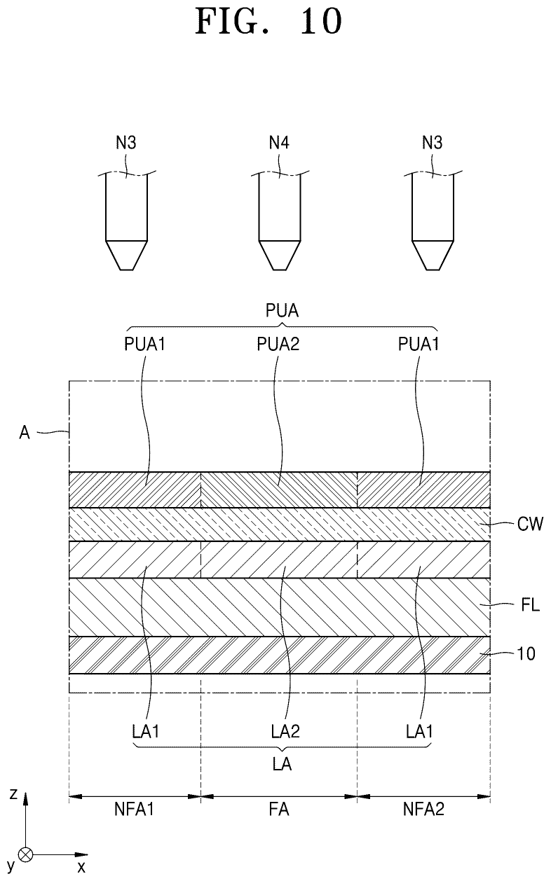

Subsequently, as shown in FIG. 10, a preliminary upper adhesive layer PUA may be formed on the cover window CW. The preliminary upper adhesive layer PUA may include a preliminary first upper adhesive layer PUA1 and a preliminary second upper adhesive layer PUA2.

In an embodiment, the first adhesive composition may be coated on a portion of the cover window CW overlapping the first non-folded area NFA1 and the second non-folded area NFA2. Accordingly, the preliminary first upper adhesive layer PUA1 overlapping the first non-folded area NFA1 and the second non-folded area NFA2 may be formed. That is, the preliminary first upper adhesive layer PUA1 may be the first adhesive composition coated on the protective film PF or the cover window CW to attach the protective film PF to the cover window CW. Together, a second adhesive composition may be coated on another portion of the cover window CW overlapping the foldable area FA. Accordingly, the preliminary second upper adhesive layer PUA2 overlapping the foldable area FA may be formed. That is, the preliminary second upper adhesive layer PUA2 may be the second adhesive composition coated on the protective film PF or the cover window CW to attach the protective film PF to the cover window CW.

The coating of the first adhesive composition and the coating of the second adhesive composition may be performed simultaneously. That is, the first adhesive composition and the second adhesive composition may be coated simultaneously. As shown in FIG. 10, the first adhesive composition may be coated on a portion of the cover window CW overlapping the first non-folded area NFA1 and the second non-folded area NFA2 using a third nozzle N3, and the second adhesive composition may be coated on the other portion of the cover window CW overlapping the foldable area FA using a fourth nozzle N4. In other words, the first adhesive composition and the second adhesive composition may be simultaneously coated on the cover window CW using the third nozzle N3 and the fourth nozzle N4. Because the effect occurring as the coating of the first adhesive composition and the coating of the second adhesive composition are simultaneously performed is described above with reference to FIGS. 7 and 8, repeated description related thereto is omitted.

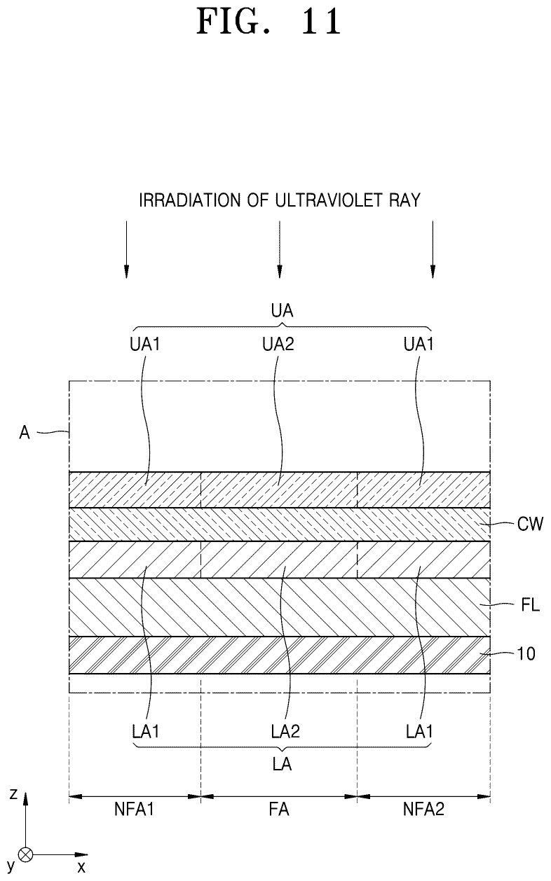

Subsequently, as shown in FIG. 11, the upper adhesive layer UA including the first upper adhesive layer UA1 and the second upper adhesive layer UA2 may be formed by irradiating a UV ray to the preliminary upper adhesive layer PUA. That is, the first upper adhesive layer UA1 may be a cured preliminary first upper adhesive layer PUA1, and the second upper adhesive layer UA2 may be a cured preliminary second upper adhesive layer PUA2. Specifically, UV rays having a light intensity of about 100 mJ/cm² to about 1000 mJ/cm² may be irradiated to the preliminary upper adhesive layer PUA. UV rays with a wavelength of about 300 nm to about 400 nm may be used for photocuring. An LED or metal halide may be used as a UV source. By irradiating UV rays to the preliminary upper adhesive layer PUA, the preliminary upper adhesive layer PUA may be photocured.

In an embodiment, a modulus of the first upper adhesive layer UA1 may be 1.5 MPa or more, and a modulus of the second upper adhesive layer UA2 may be about 0.03 MPa to about 1.5 MPa. Accordingly, the impact resistance of the first upper adhesive layer UA1 may be superior to that of the second upper adhesive layer UA2. In an embodiment, a difference between the refractive index of the first upper adhesive layer UA1 and the refractive index of the second upper adhesive layer UA2 may be about 0.1 or less. In the case where a difference between the refractive index of the first upper adhesive layer UA1 and the refractive index of the second upper adhesive layer UA2 exceeds 0.1, the boundary between the first upper adhesive layer UA1 and the second upper adhesive layer UA2 may be viewed.

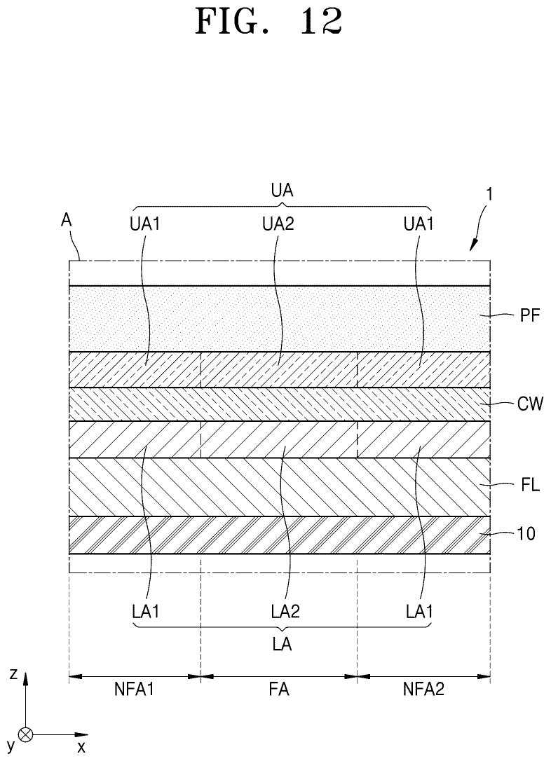

Subsequently, as shown in FIG. 12, the protective film PF may be attached to the cover window CW. Specifically, the protective film PF may be attached to the cover window CW using the upper adhesive layer UA formed on the cover window CW.

Although it is shown in FIG. 7 that the first adhesive composition and the second adhesive composition are coated on the functional layer FL attached to one surface of the display panel 10 to attach the cover window CW to the display panel 10, the disclosure is not limited thereto. In an embodiment, the first adhesive composition and the second adhesive composition may be coated on the cover window CW.

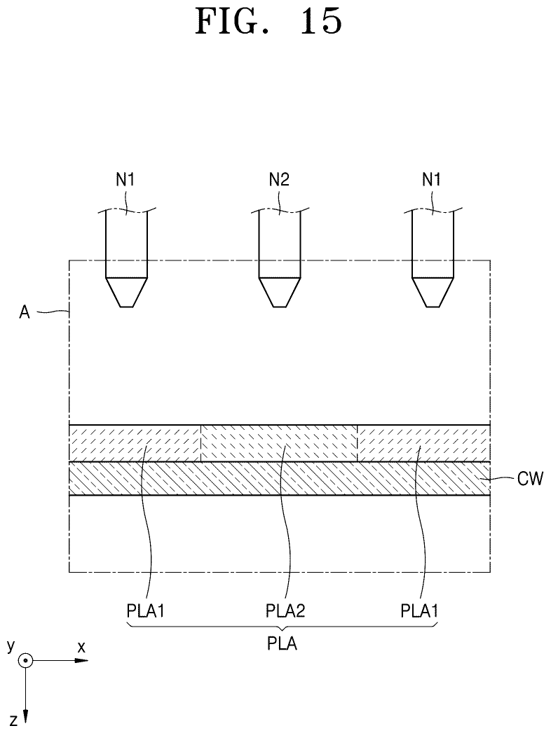

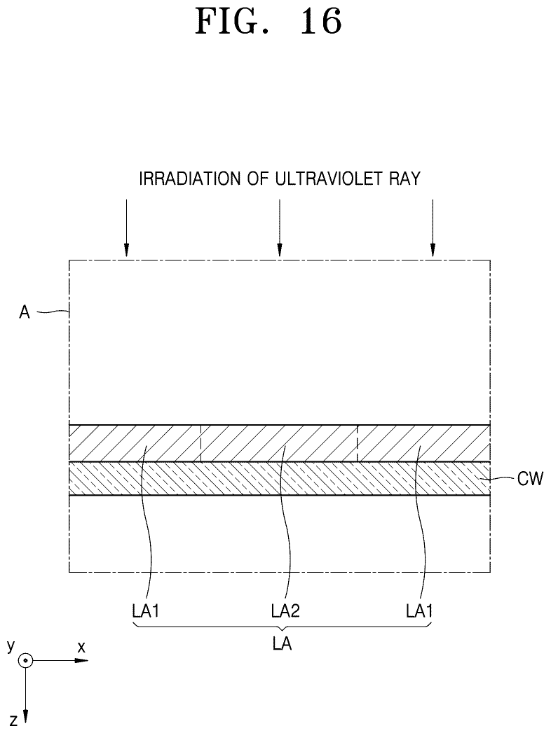

FIGS. 15 to 17 are schematic cross-sectional views to explain an embodiment of a method of manufacturing a display apparatus. Specifically, FIGS. 15 to 17 are schematic cross-sectional views showing a portion of the process of manufacturing the display apparatus 1 of FIG. 3. Because the method of manufacturing the display apparatus in an embodiment corresponds to some modified embodiments of the method of manufacturing the display apparatus described with reference to FIGS. 6 to 12, differences from the method of manufacturing the display apparatus described above with reference to FIGS. 6 to 12 are mainly described. Hereinafter, for convenience, content that repeats the content described above with reference to FIGS. 6 to 12 are omitted. In FIGS. 15 to 17, the same reference numerals as those of FIGS. 6 to 12 denote the same members, and thus, repeated descriptions thereof are omitted. As described with reference to FIG. 3, the lower adhesive layer LA attaches the cover window CW to the display panel 10 through the functional layer FL. That is, the upper surface of the lower adhesive layer LA contacts the lower surface of the cover window CW, and the lower surface of the lower adhesive layer LA which is the opposite surface of the upper surface of the lower adhesive layer LA contacts the functional layer FL. Accordingly, FIGS. 15 and 16 show the cover window CW of FIG. 3 being turned over such that the lower surface of the cover window CW faces upward.

In the method of manufacturing the display apparatus described with reference to FIGS. 6 to 12, the coating of the first adhesive composition and the coating of the second adhesive composition may be simultaneously performed. That is, the first adhesive composition and the second adhesive composition may be coated simultaneously. In the method of manufacturing the display apparatus in an embodiment, the coating of the first adhesive composition and the coating of the second adhesive composition may be simultaneously performed.

However, in the case of the method of manufacturing the display apparatus in an embodiment, as shown in FIG. 15, the preliminary lower adhesive layer PLA may be formed on the cover window CW. The preliminary lower adhesive layer PLA may include the preliminary first lower adhesive layer PLA1 and the preliminary second lower adhesive layer PLA2. In an embodiment, the first adhesive composition may be coated on a portion of the cover window CW. Accordingly, the preliminary first lower adhesive layer PLA1 may be formed on a portion of the cover window CW. Together, the second adhesive composition may be coated on another portion of the cover window CW. Accordingly, the preliminary second lower adhesive layer PLA2 may be formed on another portion of the cover window CW. As shown in FIG. 15, the first adhesive composition may be coated on a portion of the cover window CW using the first nozzle N1, and the second adhesive composition may be coated on another portion of the cover window CW using the second nozzle N2. In other words, the first adhesive composition and the second adhesive composition may be simultaneously coated on the cover window CW using the first nozzle N1 and the second nozzle N2.

Subsequently, as shown in FIG. 16, the lower adhesive layer LA including the first lower adhesive layer LA1 and the second lower adhesive layer LA2 may be formed by irradiating a UV ray to the preliminary lower adhesive layer PLA. That is, the first lower adhesive layer LA1 may be a cured preliminary first lower adhesive layer PLA1, and the second lower adhesive layer LA2 may be a cured preliminary second lower adhesive layer PLA2. Specifically, UV rays having a light intensity of about 100 mJ/cm² to about 1000 mJ/cm² may be irradiated to the preliminary lower adhesive layer PLA. UV rays with a wavelength of about 300 nm to about 400 nm may be used for photocuring. An LED or metal halide may be used as a UV source. By irradiating UV rays to the preliminary lower adhesive layer PLA, the preliminary lower adhesive layer PLA may be photocured.

In an embodiment, a modulus of the first lower adhesive layer LA1 may be 1.5 MPa or more, and a modulus of the second lower adhesive layer LA2 may be about 0.03 MPa to about 1.5 MPa. Accordingly, the impact resistance of the first lower adhesive layer LA1 may be superior to that of the second lower adhesive layer LA2. In an embodiment, a difference between the refractive index of the first lower adhesive layer LA1 and the refractive index of the second lower adhesive layer LA2 may be about 0.1 or less. In the case where a difference between the refractive index of the first lower adhesive layer LA1 and the refractive index of the second lower adhesive layer LA2 exceeds 0.1, the boundary between the first lower adhesive layer LA1 and the second lower adhesive layer LA2 may be viewed.

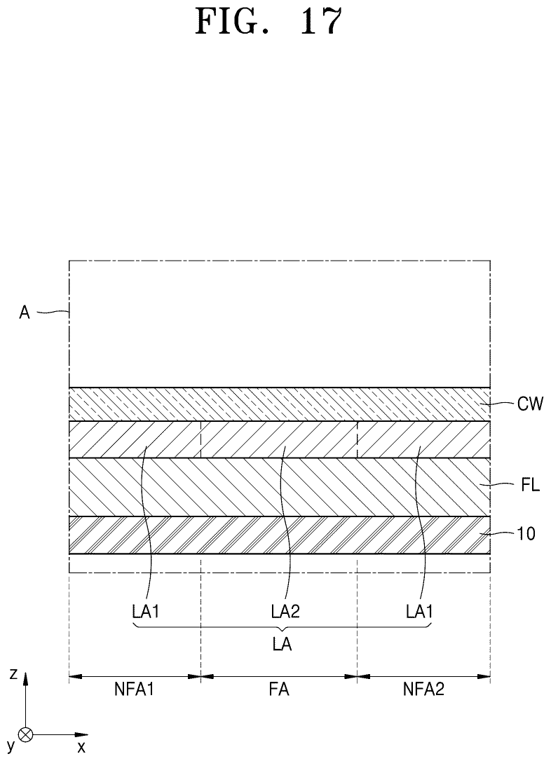

Subsequently, as shown in FIG. 17, the display panel 10 may be attached to the cover window CW using the lower adhesive layer LA. The display panel 10 may include the first non-folded area NFA1, the second non-folded area NFA2, and the foldable area FA. The foldable area FA may be disposed between the first non-folded area NFA1 and the second non-folded area NFA2. Specifically, the display panel 10 may be attached to the cover window CW such that the first non-folded area NFA1 and the second non-folded area NFA2 overlap the first lower adhesive layer LA1, and the foldable area FA overlaps the second lower adhesive layer LA2.

In an embodiment, the method of manufacturing the display apparatus with a reduced defect occurrence possibility during a manufacturing process may be implemented. However, the scope of the disclosure is not limited by this effect.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A method of manufacturing a display apparatus, the method comprising:
preparing a display panel with a functional layer attached to a surface of the display panel, the display panel including a first non-folded area, a second non-folded area, and a foldable area between the first non-folded area and the second non-folded area;
forming a preliminary lower adhesive layer on the functional layer, the preliminary lower adhesive layer including a preliminary first lower adhesive layer and a preliminary second lower adhesive layer; and
forming a lower adhesive layer by irradiating an ultraviolet ray to the preliminary lower adhesive layer, the lower adhesive layer including a first lower adhesive layer cured from the preliminary first lower adhesive layer and a second lower adhesive layer cured from the preliminary second lower adhesive layer,
wherein the forming the preliminary lower adhesive layer comprises forming the preliminary first lower adhesive layer overlapping the first non-folded area and the second non-folded area by coating a first adhesive composition on a portion of the functional layer which overlaps the first non-folded area and the second non-folded area, and forming the preliminary second lower adhesive layer overlapping the foldable area by coating a second adhesive composition on another portion of the functional layer which overlaps the foldable area,
wherein each of the first adhesive composition and the second adhesive composition includes a first crosslinkable monomer including a hydroxyl group, a second crosslinkable monomer non-including a hydroxyl group, a third crosslinkable monomer including a heterocyclic group at a terminal thereof, a fourth crosslinkable monomer including an ethylene glycol group, and an oligomer,
wherein a content of the second crosslinkable monomer contained in the first adhesive composition is less than a content of the second crosslinkable monomer contained in the second adhesive composition, and
wherein, during the forming the preliminary lower adhesive layer, the coating the first adhesive composition and the coating the second adhesive composition are simultaneously performed.

2. The method of claim 1, wherein a difference between the content of the second crosslinkable monomer contained in the first adhesive composition based on a total weight of the first crosslinkable monomer, the second crosslinkable monomer, the third crosslinkable monomer, the fourth crosslinkable monomer, and the oligomer included in the first adhesive composition, and the content of the second crosslinkable monomer contained in the second adhesive composition based on a total weight of the first crosslinkable monomer, the second crosslinkable monomer, the third crosslinkable monomer, the fourth crosslinkable monomer, and the oligomer included in the second adhesive composition, is about 5 wt % to about 45 wt %.

3. The method of claim 1, wherein a difference between a dynamic surface tension of the first adhesive composition and a dynamic surface tension of the second adhesive composition is about 0.1 millinewton per meter to about 1 millinewton per meter.

4. The method of claim 1, wherein a difference between a predetermined gravity of the first adhesive composition and a predetermined gravity of the second adhesive composition is about 0.1 or less.

5. The method of claim 1, wherein a modulus of the first lower adhesive layer is about 1.5 megapascals or more, and a modulus of the second lower adhesive layer is about 0.03 megapascal to about 1.5 megapascals.

6. The method of claim 1, wherein a difference between a refractive index of the first lower adhesive layer and a refractive index of the second lower adhesive layer is about 0.1 or less.

7. The method of claim 1, wherein the first crosslinkable monomer includes at least one of 4-hydroxybutyl (meth)acrylate, 2-hydroxypropyl (meth)acrylate, 2-hydroxyethyl (meth)acrylate, and dihydroxyhexyl (meth)acrylate.

8. The method of claim 1, wherein the second crosslinkable monomer includes at least one of 2-ethylhexyl (meth)acrylate, ethyl (meth)acrylate, methyl (meth)acrylate, n-propyl (meth)acrylate, isopropyl (meth)acrylate, pentyl (meth)acrylate, n-octyl (meth)acrylate, isooctyl (meth)acrylate, isononyl (meth)acrylate, n-butyl (meth)acrylate, isobutyl (meth)acrylate, n-hexyl (meth)acrylate, n-nonyl (meth)acrylate, isoamyl (meth)acrylate, n-decyl (meth)acrylate, isodecyl (meth)acrylate, dodecyl (meth)acrylate, isobornyl (meth)acrylate, cyclohexyl (meth)acrylate, phenyl (meth)acrylate, benzyl (meth)acrylate, isostearyl (meth)acrylate, and 2-methylbutyl (meth)acrylate.

9. The method of claim 1, wherein the third crosslinkable monomer includes at least one of tetrahydrofurfuryl (meth)acrylate, (tetrahydro-2H-pyran-2-yl)methyl (meth)acrylate, (oxetan-2-yl)methyl (meth)acrylate, (oxepan-2-yl)methyl (meth)acrylate, (2-oxa-bicyclo[2.2.2]octan-6-yl)methyl (meth)acrylate, and (7-oxa-bicyclo[2.2.1]heptan-2-yl)methyl (meth)acrylate.

10. The method of claim 1, wherein the fourth crosslinkable monomer includes at least one of di(ethylene glycol) 2-ethylhexyl ether (meth)acrylate and ethylene glycol (meth)acrylate.

11. The method of claim 1, further comprising attaching a cover window to the functional layer using the lower adhesive layer.

12. The method of claim 11, further comprising:
forming a preliminary upper adhesive layer on the cover window, wherein the preliminary upper adhesive layer includes a preliminary first upper adhesive layer and a preliminary second upper adhesive layer;
forming an upper adhesive layer by irradiating an ultraviolet ray to the preliminary upper adhesive layer, wherein the upper adhesive layer includes a first upper adhesive layer cured from the preliminary first upper adhesive layer and a second upper adhesive layer cured from the preliminary second upper adhesive layer; and
attaching a protective film to the cover window using the upper adhesive layer,
wherein the forming the preliminary upper adhesive layer comprises forming the preliminary first upper adhesive layer overlapping the first non-folded area and the second non-folded area by coating the first adhesive composition on a portion of the cover window which overlaps the first non-folded area and the second non-folded area, and forming the preliminary second upper adhesive layer overlapping the foldable area by coating the second adhesive composition on another portion of the cover window which overlaps the foldable area.

13. A method of manufacturing a display apparatus, the method comprising:
forming a preliminary lower adhesive layer on a cover window, the preliminary lower adhesive layer including a preliminary first lower adhesive layer and a preliminary second lower adhesive layer; and
forming a lower adhesive layer by irradiating an ultraviolet ray to the preliminary lower adhesive layer, the lower adhesive layer including a first lower adhesive layer cured from the preliminary first lower adhesive layer and a second lower adhesive layer cured from the preliminary second lower adhesive layer,
wherein the forming the preliminary lower adhesive layer includes forming the preliminary first lower adhesive layer by coating a first adhesive composition on a portion of the cover window, and forming the preliminary second lower adhesive layer by coating a second adhesive composition on another portion of the cover window,
wherein each of the first adhesive composition and the second adhesive composition includes a first crosslinkable monomer including a hydroxyl group, a second crosslinkable monomer non-including a hydroxyl group, a third crosslinkable monomer including a heterocyclic group at a terminal thereof, a fourth crosslinkable monomer including an ethylene glycol group, and an oligomer,
wherein a content of the second crosslinkable monomer contained in the second adhesive composition is less than a content of the second crosslinkable monomer contained in the first adhesive composition, and
wherein, during the forming the preliminary lower adhesive layer, the coating the first adhesive composition and the coating the second adhesive composition are simultaneously performed.

14. The method of claim 13, wherein a difference between the content of the second crosslinkable monomer contained in the first adhesive composition based on a total weight of the first crosslinkable monomer, the second crosslinkable monomer, the third crosslinkable monomer, the fourth crosslinkable monomer, and the oligomer included in the first adhesive composition, and
the content of the second crosslinkable monomer contained in the second adhesive composition based on a total weight of the first crosslinkable monomer, the second crosslinkable monomer, the third crosslinkable monomer, the fourth crosslinkable monomer, and the oligomer included in the second adhesive composition, is about 5 wt % to about 45 wt %.

15. The method of claim 13, wherein a difference between a dynamic surface tension of the first adhesive composition and a dynamic surface tension of the second adhesive composition is about 0.1 millinewton per meter to about 1 millinewton per meter.

16. The method of claim 13, wherein a difference between a predetermined gravity of the first adhesive composition and a predetermined gravity of the second adhesive composition is about 0.1 or less.

17. The method of claim 13, wherein a modulus of the first lower adhesive layer is about 1.5 megapascals or more, and a modulus of the second lower adhesive layer is about 0.03 megapascal to about 1.5 megapascals.

18. The method of claim 13, wherein a difference between a refractive index of the first lower adhesive layer and a refractive index of the second lower adhesive layer is about 0.1 or less.

19. The method of claim 13, further comprising attaching a display panel to the cover window using the lower adhesive layer, wherein the display panel includes a first non-folded area, a second non-folded area, and a foldable area between the first non-folded area and the second non-folded area,
wherein the attaching the display panel comprises attaching the display panel to the cover window so that the first non-folded area and the second non-folded area overlap the first lower adhesive layer, and the foldable area overlaps the second lower adhesive layer.

20. A method of manufacturing an electronic apparatus comprising the method of claim 1.
